(19) United States
(12) Patent Application Publication
(10) Pub. No.: US 2025/0323138 A1
(43) Pub. Date: Oct. 16, 2025

(54) APPLICATION BOARD AND A SEMICONDUCTOR PACKAGE MOUNTED THEREON FOR REDUCING CREEPAGE CURRENTS

(71) Applicant: Infineon Technologies Austria AG, Villach (AT)

(72) Inventors: Edward Fürgut, Dasing (DE); Shu Hui Goh, Muar (MY); Teck Sim Lee, Paya Rumput (MY)

(21) Appl. No.: 19/174,119

(22) Filed: Apr. 9, 2025

(30) Foreign Application Priority Data
Apr. 10, 2024 (DE) 102024110025.7

(51) Int. Cl. H01L 23/498; H01L 23/29; H01L 23/31

(52) U.S. Cl. CPC H01L 23/49861; H01L 23/315; H01L 23/296

(57) ABSTRACT

An application board includes a first main face and a plurality of electrical contact areas disposed on the first main face. The electrical contact areas include one or more first electrical contact areas and one or more second electrical contact areas. A recess such as a slot or a groove is disposed in the first main face. The recess spaces a first portion of the application board from a second portion of the application board. The first electrical contact areas are disposed on the first portion of the application board and the second electrical contact areas are disposed on the second portion of the application board.

### TECHNICAL FIELD

The present disclosure is related to an application board and a semiconductor device module comprising the application board and a semiconductor package mounted thereon.

### BACKGROUND

Electronic devices such as e.g. power semiconductors may be operated with high voltages. Here, the devices may need to comply with electrical insulation requirements in accordance with given safety standards. Electronic devices constantly have to be improved. In particular, it may be desirable to fulfil required safety standards without reducing the performance and the quality of the devices. In this regard, it may be particularly desirable to increase creepage distances of the devices. In addition, it may be desirable to reduce system costs and to provide higher power density.

For these and other reasons there is a need for the present disclosure.

### SUMMARY

A first aspect of the present disclosure is related to an application board comprising a first main face and a plurality of electrical contact areas disposed on the first main face, the plurality of electrical contact areas comprising one or more first electrical contact areas and one or more second electrical contact areas, and a recess, namely a slot or a groove disposed in the first main face, the recess spacing a first portion of the application board from a second portion of the application board, wherein the first electrical contact areas are disposed on the first portion of the application board and the second electrical contact areas are disposed on the second portion of the application board.

According to an embodiment of the application board of the first aspect, the first electrical contact areas are arranged on the first portion of the application board at a distance in a range between 0 mm and 3 mm from an edge of the first section facing the recess.

According to an embodiment of the application board of the first aspect, thickness of the application board can be in a range from 1 mm through 5 mm. In the case of a groove as the recess, the thickness of the groove can be in a range from 0.1 mm to 2.0 mm or more.

According to an embodiment of the application board of the first aspect, the width of the recess is in a range from 0.25 mm to 5 mm.

According to an embodiment of the application board of the first aspect, two or more first electrical contact areas are arranged side by side along a row.

According to an embodiment of the application board of the first aspect, the application board comprises one or more of a printed circuit board (PCB), a direct copper bond (DCB) substrate, an active metal braze (AMB) substrate, insulated metal substrate (IMS), or any other interposer.

A second aspect of the present disclosure is related to a semiconductor device module comprising an application board according to the first aspect, and a semiconductor package mounted onto the application board.

According to an embodiment of the semiconductor device module of the second aspect, the semiconductor package comprises a semiconductor transistor die and a plurality of external contacts comprising first external contacts and second external contacts, wherein the semiconductor transistor die comprises a load path, wherein the first external contacts are connected with the load path of the semiconductor transistor die.

According to an embodiment of the semiconductor device module of the second aspect, wherein the semiconductor package comprises a first main surface facing the application board, in which first main surface a recess is formed, whereby the semiconductor package is mounted on the application board in such a way that the recess of the semiconductor package comes to lie above the recess of the application board.

According to an embodiment of the semiconductor device module of the second aspect, the recess formed in the first main surface of the semiconductor package is either a groove or a recess at the edge of the package.

According to an embodiment of the semiconductor device module of the second aspect, an inner wall of the groove is adjacent and coplanar with an inner wall of the recess.

According to an embodiment of the semiconductor device module of the second aspect, the semiconductor package comprises a leadframe, wherein the leadframe comprises a die pad and a plurality of leads.

According to an embodiment of the semiconductor device module of the second aspect, the recess extends from a first sidewall to an opposing second sidewall of the semiconductor package.

According to an embodiment of the semiconductor device module of the second aspect, the semiconductor transistor die comprises one or more of a vertical semiconductor transistor die, a semiconductor power transistor die, an IGBT die, a MOSFET die, a JFET die, a CoolMOS die, a wide band gap semiconductor transistor die, in particular a SiC transistor die or a GaN transistor die.

According to an embodiment of the semiconductor device module of the second aspect, the semiconductor package is any kind of an SMD bottom side cooling package or a double sided cooling package.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIGS. 1A and 1B show a cross-sectional side view (FIG. 1A) and a perspective view (FIG. 1B) on an exemplary application board comprising a slot.

FIGS. 2A and 2B show a cross-sectional side view (FIG. 2A) and a perspective view (FIG. 2B) on an exemplary application board comprising a groove.

FIGS. 3A to 3C show a cross-sectional side view (FIG. 3A), a perspective view (FIG. 3B), and a bottom view (FIG. 3C) on an exemplary semiconductor device module with the application board comprising a slot.

FIGS. 4A and 4B show a perspective view (FIG. 4A), and a bottom view (FIG. 4B) on an exemplary semiconductor device module comprising three semiconductor packages and with the application board comprising a slot.

FIGS. 5A to 5C show a cross-sectional side view (FIG. 5A), a perspective view (FIG. 5B), and a bottom view (FIG. 5C) on an exemplary semiconductor device module with the application board comprising a groove.

FIGS. 6A and 6B show a perspective view (FIG. 6A), and a bottom view (FIG. 6B) on an exemplary semiconductor device module comprising three semiconductor packages and with the application board comprising a slot.

FIGS. 7A to 7C show a cross-sectional side view (FIG. 7A), a perspective view (FIG. 7B), and a bottom view (FIG. 7C) on an exemplary semiconductor device module with an SMD leadless semiconductor package and the application board comprising a slot.

FIGS. 8A and 8B show a cross-sectional side view of an SMD leadless semiconductor package semiconductor package with an exemplary modified leadframe (FIG. 8A) and a semiconductor device module containing the semiconductor package with the modified leadframe (FIG. 8B).

FIGS. 9A to 9C show a cross-sectional side view (FIG. 9A), a perspective view (FIG. 9B), and a bottom view (FIG. 9C) on an exemplary semiconductor device module with the semiconductor package as shown in FIGS. 8A-8B and an application board comprising a groove.

FIGS. 10A and 10B show a cross-sectional side view of a semiconductor package with another exemplary modified leadframe (FIG. 10A) and a semiconductor device module containing an SMD leaded semiconductor package with the modified leadframe (FIG. 10B).

FIGS. 11A to 11C show a cross-sectional side view (FIG. 11A), a perspective view (FIG. 11B), and a bottom view (FIG. 11C) on the exemplary semiconductor device module as shown in FIG. 10B.

FIGS. 12A to 12C show a cross-sectional side view (FIG. 12A), a perspective view (FIG. 12B), and a bottom view (FIG. 12C) on an exemplary semiconductor device module with an SMD leaded semiconductor package and the application board comprising a groove.

FIGS. 13A and 13B show a cross-sectional side view of an SMD leaded semiconductor package with another exemplary modified leadframe (FIG. 13A) and a semiconductor device module containing the semiconductor package with the modified leadframe with an application board having a slot (FIG. 13B).

FIGS. 14A to 14C show a cross-sectional side view (FIG. 14A), a perspective view (FIG. 14B), and a bottom view (FIG. 14C) on an exemplary semiconductor device module with the same semiconductor package as the one of FIGS. 13A-13B together with an application board having a slot.

FIGS. 15A to 15C show a cross-sectional side view (FIG. 15A), a perspective view (FIG. 15B), and a bottom view (FIG. 15C) on an exemplary semiconductor device module with the same semiconductor package as the one of FIGS. 14A-14C together with an application board having a groove.

FIGS. 16A and 16B show a cross-sectional side view of an SMD leaded semiconductor package with another exemplary modified leadframe (FIG. 16A) and a semiconductor device module containing the semiconductor package with the modified leadframe with an application board having a slot (FIG. 16B).

FIGS. 17A to 17C show a cross-sectional side view (FIG. 17A), a perspective view (FIG. 17B), and a bottom view (FIG. 17C) on an exemplary semiconductor device module with the same semiconductor package as the one of FIGS. 16A-16B together with an application board having a slot.

FIGS. 18A to 18C show a cross-sectional side view (FIG. 18A), a perspective view (FIG. 18B), and a bottom view (FIG. 18C) on an exemplary semiconductor device module with the same semiconductor package as the one of FIGS. 16A-16B together with an application board having a groove.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

The examples of a semiconductor device module may use various types of transistor devices. The examples may also use horizontal or vertical transistor devices wherein those structures may be provided in a form in which all contact elements of the transistor device are provided on one of the main faces of the semiconductor die (horizontal transistor structures) or in a form in which at least one electrical contact element is arranged on a first main face of the semiconductor die and at least one other electrical contact element is arranged on a second main face opposite to the main face of the semiconductor die (vertical transistor structures) like, for example, MOS transistor structures or IGBT (Insulated Gate Bipolar Transistor) structures.

According to an embodiment of the semiconductor package, the semiconductor transistor die is a semiconductor power transistor die. Here, the term “power semiconductor transistor die” may refer to a semiconductor die providing at least one of high voltage blocking or high current-carrying capabilities. A power semiconductor die may be configured for high currents having a maximum current value of a few Amperes, such as e.g. 10 A, 250A, 600A, 1000A, or a maximum current value of up to or even exceeding 1000 A. Similarly, voltages associated with such current values may have values of a few Volts to a few tens or hundreds or even thousands of Volts.

The examples of a semiconductor package may comprise an encapsulant or encapsulating material having the semiconductor transistor die and the semiconductor driver die embedded therein. The encapsulating material can be any electrically insulating material like, for example, any kind of molding material, any kind of resin material, or any kind of epoxy material. The encapsulating material can also be a polymer material, a polyimide material, a thermoplast material, a silicone material, a ceramic material, and a glass material. The encapsulating material may also comprise any of the above-mentioned materials and further include filler materials embedded therein like, for example, thermally conductive increments like thermally conductive particles like, for example, made of AlO, BNi, AlNi, SiN, diamond, or any other thermally conductive particles.

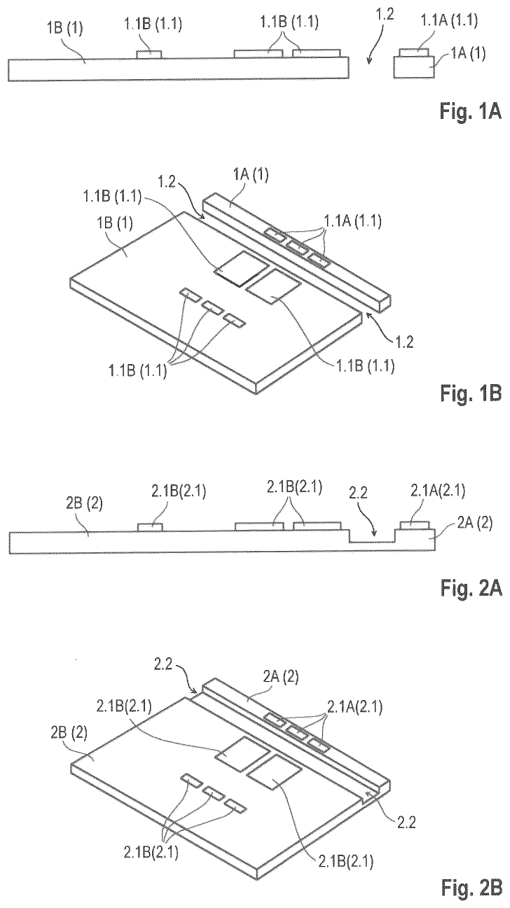

FIGS. 1A and 1B show a cross-sectional side view (FIG. 1A) and a perspective view (FIG. 1B) of an exemplary application board comprising a slot.

The application board 1 of FIGS. 1A and 1B may be a conventional printed circuit board (PCB). It comprises a first upper main face and a plurality of electrical contact areas 1.1, 1.1A, 1.1B disposed thereon, the plurality of electrical contact areas 1.1, 1.1A, 1.1B comprising one or more first electrical contact areas 1.1A and one or more second electrical contact areas 1.1B. The application board 1 further comprises a slot 1.2 formed in the first main face of the PCB 1.

The slot 1.2 separates the PCB 1 into two portions 1A und 1B of different sizes. A first portion 1A, i.e. the larger one of the two portions 1A and 1B is intended for mounting a semiconductor package on it. The first contact areas 1.1A are arranged on a first portion 1A of the two portions 1A and 1B of the PCB 1. They can be arranged at a distance of between 0 mm and 3 mm from an edge of the first section 1A facing the recess.

The first electrical contact areas 1.1A are intended to be connected to certain external contacts of the semiconductor package, as will be seen later.

The application board 1 also has second electrical contact areas 1.1B, which are arranged on the second portion 2A and are intended to be connected to other external contacts of the semiconductor package.

In FIGS. 1A and 1B, three first electrical contact areas 1.1A are shown which are arranged side by side along a row, wherein the slot 1.2 is spaced by the short distance from the row of the two or more first electrical contact areas 1.1A. The three first electrical contact areas 1.1A can be identical and can be equally spaced from the edge of the first portion 1A. They can furthermore be directly adjacent to each other laterally or also slightly spaced apart.

Furthermore, the slot 1.2 can have a constant width over its entire length, which can be in a range between 3 mm and 5 mm, for example.

Fabricating and handling the PCB 1 can be done by attaching a preform of the PCB onto a sheet like an adhesive film, then cutting out the slot 1.2 and then mounting a semiconductor package thereon.

FIGS. 2A and 2B show a cross-sectional side view (FIG. 2A) and a perspective view (FIG. 2B) on an exemplary application board comprising a groove.

The application board 2 of FIGS. 2A and 2B may also be a conventional printed circuit board (PCB). It comprises a first upper main face and a plurality of electrical contact areas 2.1, 2.1A, 2.1B disposed thereon, the plurality of electrical contact areas 2.1, 2.1A, 2.1B comprising one or more first electrical contact areas 2.1A and one or more second electrical contact areas 1.1B. The application board 20 further comprises a groove 2.2 disposed in the first main face.

The groove 2.2 separates the PCB 2 into two portions 2A und 2B of different sizes. A first portion 2A, i.e. the larger one of the two portions 2A and 2B is intended for mounting a semiconductor package on it. The first contact areas 2.1A are arranged on a first portion 2A of the two portions 2A and 2B of the PCB 2. They can be arranged at a distance of between 0 mm and 3 mm from an edge of the first section 2A facing the recess.

The application board 2 therefore differs from the application board 1 only in the type of the recess. While the application board 1 has a slot 1.2 as the recess, the application board 2 has a groove 2.2, which can, for example, have a depth corresponding to half the thickness of the PCB 2.

Otherwise, all other elements and properties of the application board 2, in particular the first electrical contact areas 2.1A and the second electrical contact areas 2.1B, have the same properties and functionalities as the corresponding elements of the application board 1 of FIGS. 1A and 1B. The specified numerical values for dimensions and distances can also be the same.

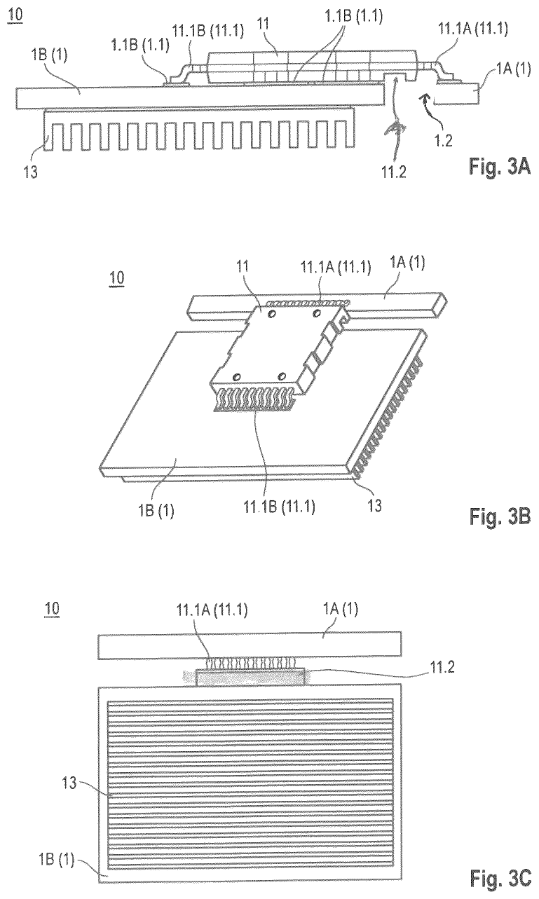

FIGS. 3A to 3C show a cross-sectional side view (FIG. 3A), a perspective view (FIG. 3B), and a bottom view (FIG. 3C) on an exemplary semiconductor device module with the application board comprising a slot.

The semiconductor device module 10 of FIGS. 3A to 3C comprises an application board 1 like, for example, a PCB 1 such as that shown and described in FIGS. 1A and 1B, the PCB comprising a slot 1.2. Furthermore the semiconductor device module 10 comprises a semiconductor package 11 mounted onto the PCB 1.

The semiconductor package 11 comprises a semiconductor transistor die (not shown) and a plurality of external contacts 11.1 comprising first external leads 11.1A and second external leads 11.1B, wherein the semiconductor transistor die comprises a load path, wherein the first external leads 11.1A are connected with the load path of the semiconductor transistor die. More specifically, the semiconductor transistor die may comprise a vertical transistor die like, for example, an IGBT die comprising source and gate pads disposed on a first upper main surface and a drain pad disposed on a second lower main surface of the IGBT die, so that the load path is between the source and the drain of the semiconductor transistor die.

The semiconductor package 11 furthermore comprises a first main surface facing the PCB 1, which first main surface comprises a groove 11.2, whereby the semiconductor package 11 is mounted on the PCB 1 in such a way that the groove 11.2 of the semiconductor package 11 comes to lie above the slot 1.2 of the PCB 1. It can in particular be the case that an inner lateral wall of the groove 11.2 is adjacent and coplanar with an inner lateral wall of the slot 1.2 as it is realized in the example of the semiconductor device module of FIGS. 3A to 3C. The slot 1.2 of the application board 1 and the recess 11.2 of the semiconductor package 11 form a contiguous space. The same applies to the embodiments shown below with a trench 2.2 of the application board 2.

The groove 11.2 preferably extends from a first sidewall to an opposing sidewall of the semiconductor package 11 with a constant thickness which can be in a range from 1 m to 3 mm.

This design serves to avoid or at least greatly reduce creepage currents between the electrical contacts 1.1B and 1.1A. Without the presence of the slot 1.2 in the PCB 1 and the trench 11.2 in the semiconductor package, there would be a creepage current path between the right-sided electrical contact 1.1B, with which the semiconductor package 11 is mounted on the second portion 1B of the PCB 1, and the electrical contact 1.1A on the first portion 1A of the PCB 1. The slot 1.2 and the groove 11.2 can therefore effectively reduce creepage currents between the aforementioned contacts. With this improved resistance to leakage currents, the semiconductor transistor can be operated with higher load voltages.

The semiconductor device module 10 is designed as a component for bottom-side cooling. For this purpose, a heat sink 13 can be attached to the underside of the PCB 1.

The second external leads 11.1B are connected with left-most second electrical contact areas 1.1B on the PCB 1 through which second external leads 11.1B, for example, control signals can be fed to the gate contact of the IGBT.

It can furthermore be the case that the recess 1.2, 2.2 of the application board 1, 2 and the recess 11.2 of the semiconductor package 11 are filled with a dielectric encapsulant. The dielectric encapsulant may comprise one or more of a dielectric mold compound, a thermally conductive filling material, a silicone, or a silicone based material. With such an additional measure, the insulation strength can be further increased, even up to a situation in which practically no leakage current can flow. The dielectric encapsulant can be filled in liquid form or as a granulate, for example using a dispensing process. This variant can also be used for all other examples of semiconductor packages shown below.

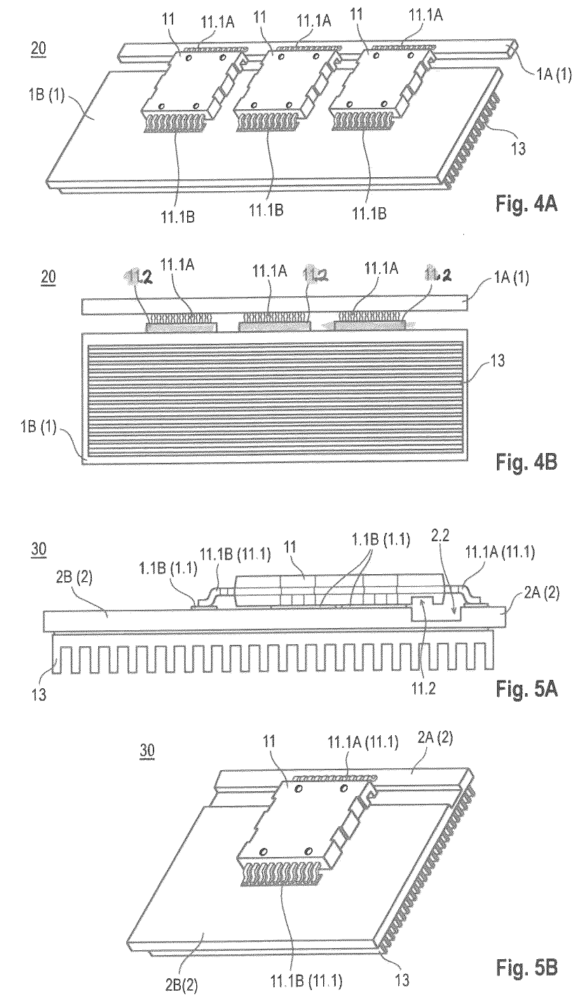

FIGS. 4A and 4B show a perspective view (FIG. 4A) and a bottom view (FIG. 4B) on an exemplary semiconductor device module comprising three semiconductor packages and with the application board comprising a slot.

The semiconductor device module 20 of FIGS. 4A and 4B comprises an application board 1 like, for example, a PCB 1 such as that shown and described in FIGS. 1A and 1B. Furthermore the semiconductor device module 20 comprises three semiconductor packages 11 mounted onto the PCB 1. The three semiconductor packages 11 are mounted onto the PCB 1 in the same way as was shown in FIGS. 3A to 3C so that all reference numbers have been retained.

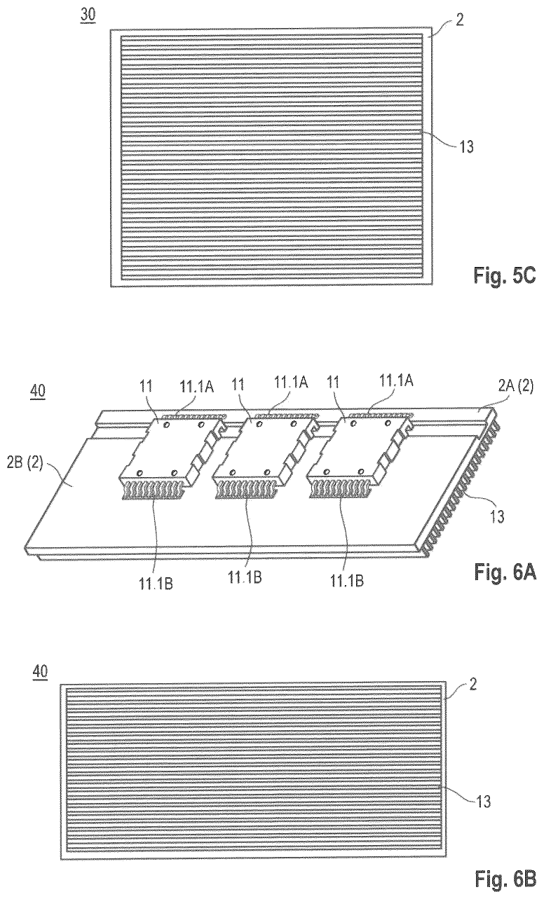

FIGS. 5A to 5C show a cross-sectional side view (FIG. 5A), a perspective view (FIG. 5B), and a bottom view (FIG. 5C) on an exemplary semiconductor device module with the application board comprising a groove.

The semiconductor device module 30 of FIGS. 5A to 5C comprises an application board 2 like, for example, a PCB 2 such as that shown and described in FIGS. 2A and 2B, the PCB 2 comprising a groove 2.2. Furthermore the semiconductor device module 30 comprises a semiconductor package 11 mounted onto the PCB 2. The semiconductor package 11 is mounted onto the PCB 2 in a similar way as was shown in FIGS. 3A to 3C so that most reference numbers have been retained.

In particular, the semiconductor package 11 further comprises a first main surface facing the PCB 2, which first main surface comprises a groove 11.2, whereby the semiconductor package 11 is mounted on the PCB 2 in such a way that the groove 11.2 of the semiconductor package 11 comes to lie above the groove 2.2 of the PCB 2. It can in particular be the case that an inner lateral wall of the groove 11.2 is adjacent and coplanar with an inner lateral wall of the groove 2.2 in a similar way as it is realized in the example of the semiconductor device module of FIGS. 3A to 3C.

FIGS. 6A and 6B show a perspective view (FIG. 6A) and a bottom view (FIG. 6B) on an exemplary semiconductor device module comprising three semiconductor packages and with the application board comprising a slot.

The semiconductor device module 40 of FIGS. 6A and 6B comprises an application board 1 like, for example, a PCB 2 such as that shown and described in FIGS. 1A and 1B. Furthermore the semiconductor device module 20 comprises three semiconductor packages 11 mounted onto the PCB 2. The three semiconductor packages 11 are mounted onto the PCB 1 in the same way as was shown in FIGS. 5A to 5C so that all reference numbers have been retained.

The examples of semiconductor device modules described so far contain semiconductor packages with external contacts in the form of leads, in particular bent leads. However, other semiconductor packages can also be used, as will be described further below.

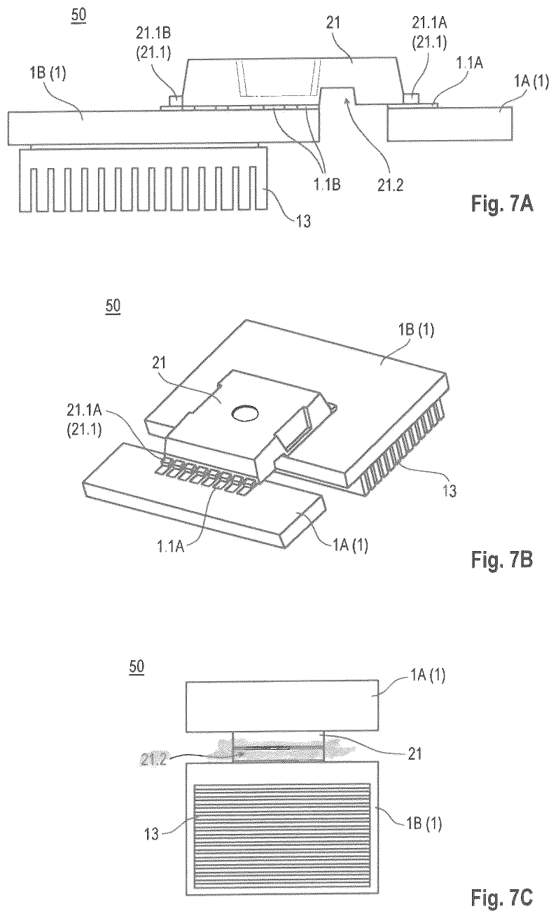

FIGS. 7A to 7C show a cross-sectional side view (FIG. 7A), a perspective view (FIG. 7B), and a bottom view (FIG. 7C) on an exemplary semiconductor device module with an SMD (surface mount device) leadless semiconductor package and the application board comprising a slot.

The semiconductor device module 50 of FIGS. 7A to 7C comprises an application board 1 like, for example, a PCB 1 such as that shown and described in FIGS. 1A and 1B, the PCB 1 comprising a slot 1.2. Furthermore the semiconductor device module 50 comprises a semiconductor package 21 mounted onto the PCB 1.

The semiconductor device module 50 of FIGS. 7A to 7C comprises a semiconductor package 21 having external contacts 21 in the form of horizontal outside extensions of the inner portions of electrical connectors which can be part of a leadframe. The semiconductor package 21 can thus be attached to the PCB 1 by use of surface mount technology. Otherwise the electrical functionality of the external contacts 21 is the same as that of the leads 11.1 as was described in connection with FIGS. 3A to 3C. Furthermore the semiconductor package comprises a groove 21.2 which corresponds to the groove 11.1 of the semiconductor package 11.

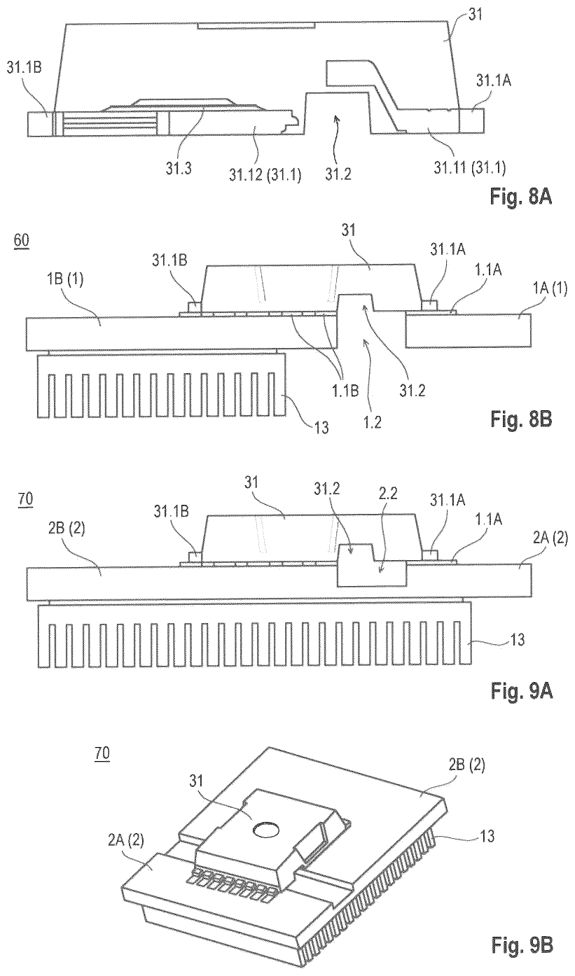

FIGS. 8A and 8B show a cross-sectional side view of an SMD leadless semiconductor package semiconductor package with an exemplary modified leadframe (FIG. 8A) and a semiconductor device module containing the semiconductor package with the modified leadframe (FIG. 8B).

The semiconductor package 31 as shown in FIG. 8A comprises a leadframe 31.1 which is embedded in an encapsulant. The semiconductor package 31 further comprises a groove 31.2 which corresponds to the groove 11.1 of the semiconductor package 11. The leadframe 31.1 comprises a right-side portion 31.11 which is bent upwards to extend over the groove 31.2, and a left-side portion 31.12 which comprises a die pad onto which a semiconductor transistor die 31.3 is mounted. The right-side portion 31.1 is connected with first flat external contacts 31.1A, and the left-side portion 31.12 is as well connected with second flat external contacts 31.1B, both the first and second external contacts 31.1A and 31.1B allow surface mounting of the semiconductor package 31 onto contact areas of an application board such as a PCB. The right-side portion 31.1 of the leadframe 31.1 can be connected by wire bonds (not shown) to the left-side portion 31.12 or to the semiconductor die 31.3.

The semiconductor device module 60 of FIG. 8B comprises an application board 1 like, for example, a PCB 1 such as that shown and described in FIGS. 1A and 1B, the PCB 1 comprising a slot 1.2. Furthermore the semiconductor device module 60 comprises a semiconductor package 31 as that shown in FIG. 8A mounted onto the PCB 1. Other elements of the semiconductor device module 60 correspond in their functionality to the corresponding elements of the semiconductor devices modules shown above, so that the corresponding reference numbers have been retained.

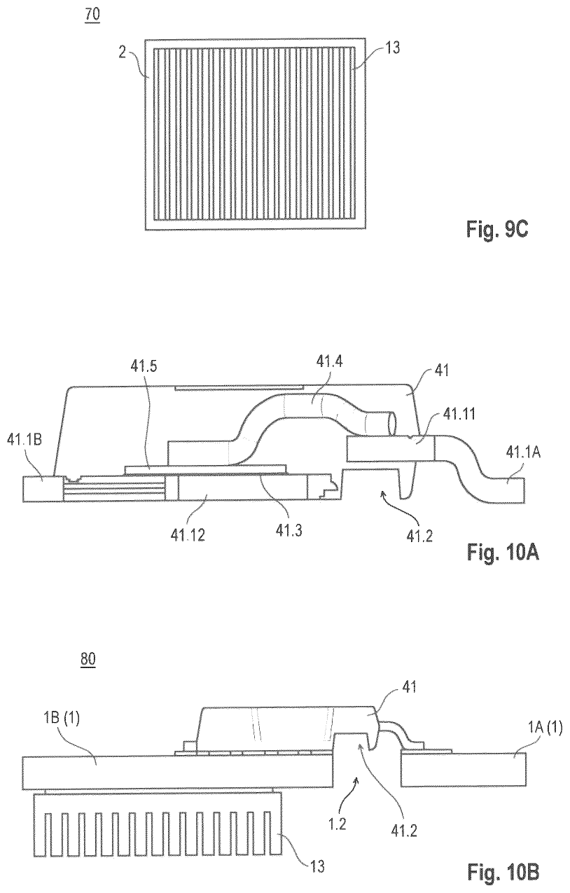

FIGS. 9A to 9C show a cross-sectional side view (FIG. 9A), a perspective view (FIG. 9B), and a bottom view (FIG. 9C) on an exemplary semiconductor device module with the semiconductor package as shown in FIGS. 8A-8B and a PCB comprising a groove.

The semiconductor device module 70 of FIGS. 9A to 9C comprises an application board 2 like, for example, a PCB 2 such as that shown and described in FIGS. 2A and 2B, the PCB 2 comprising a groove 2.2. Furthermore the semiconductor device module 70 comprises a semiconductor package 31 such as that shown and described in connection with FIGS. 8A and 8B, the semiconductor package 31 mounted onto the PCB 2. The semiconductor package 31 is mounted onto the PCB 2 in a similar way as was shown in FIGS. 3A to 3C so that most reference numbers have been retained.

FIGS. 10A and 10B show a cross-sectional side view of a semiconductor package with another exemplary modified leadframe (FIG. 10A) and a semiconductor device module containing an SMD leaded semiconductor package with the modified leadframe (FIG. 10B).

The semiconductor package 41 as shown in FIG. 10A comprises a leadframe 41.1 which is embedded in an encapsulant. The semiconductor package 41 further comprises a groove 41.2 which corresponds to the groove 11.1 of the semiconductor package 11. The leadframe 41.1 comprises a right-side portion 41.11 which is bent upwards to extend over the groove 41.2, and a left-side portion 41.12 which comprises a die pad onto which a semiconductor transistor die 41.3 is mounted. The right-side portion 41.1 is connected with first external contacts in the form of leads 41.1A, and the left-side portion 41.12 is with second external contact elements in the form of flat external contacts 41.1B, both the first and second external contacts 41.1A and 41.1B allow surface mounting of the semiconductor package 41 onto contact areas of an application board such as a PCB. The right-side portion 41.11 of the leadframe 41.1 is connected by a thick bond wire 41.4 to a metallic layer 41.5 disposed on the semiconductor transistor die 41.3.

The semiconductor device module 80 of FIG. 10B comprises an application board 1 like, for example, a PCB 1 such as that shown and described in FIGS. 1A and 1B, the PCB 1 comprising a slot 1.2. Furthermore the semiconductor device module 80 comprises a semiconductor package 41 as that shown in FIG. 10A mounted onto the PCB 1. Other elements of the semiconductor device module 80 correspond in their functionality to the corresponding elements of the semiconductor devices modules shown above, so that the corresponding reference numbers have been retained.

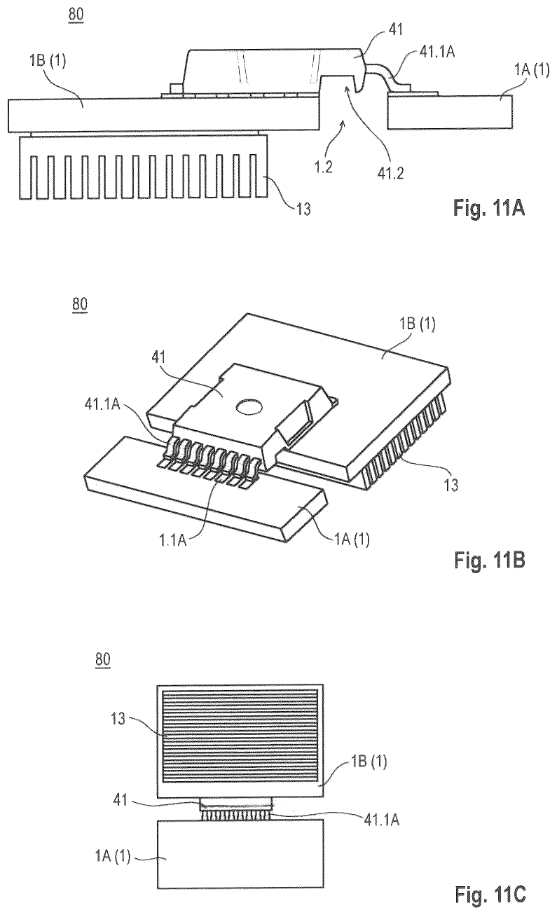

FIGS. 11A to 11C show a cross-sectional side view (FIG. 11A), a perspective view (FIG. 11B), and a bottom view (FIG. 11C) on the exemplary semiconductor device module 80 as shown in FIG. 10B.

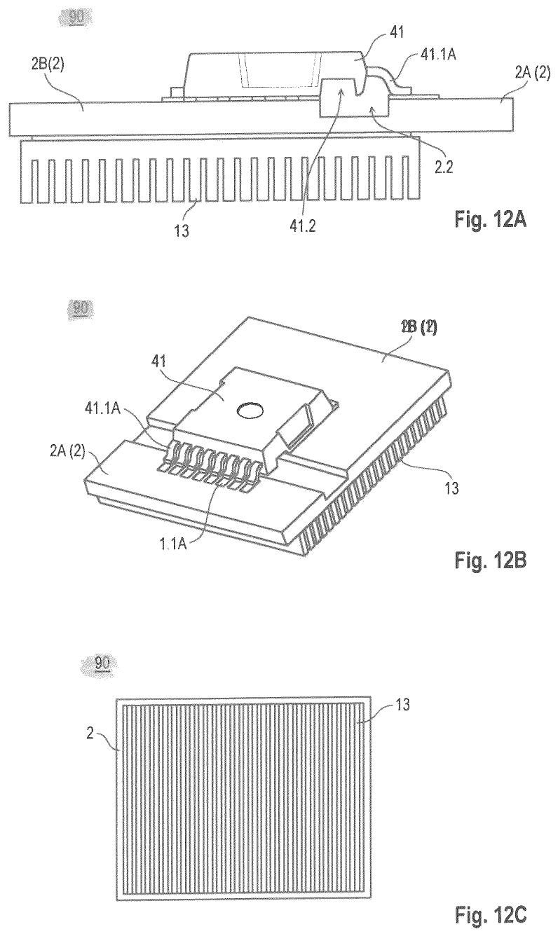

FIGS. 12A to 12C show a cross-sectional side view (FIG. 12A), a perspective view (FIG. 12B), and a bottom view (FIG. 12C) on an exemplary semiconductor device module with an SMD leaded semiconductor package and the application board comprising a groove.

The semiconductor device module 90 of FIGS. 12A to 12C comprises an application board 2 like, for example, a PCB 2 such as that shown and described in FIGS. 2A and 2B, the PCB 2 comprising a groove 2.2. Furthermore the semiconductor device module 90 comprises a semiconductor package 41 as shown in FIG. 10A mounted onto the PCB 2. The semiconductor package 41 is mounted onto the PCB 2 in a similar way as was shown in FIGS. 11A to 11C so that most reference numbers have been retained.

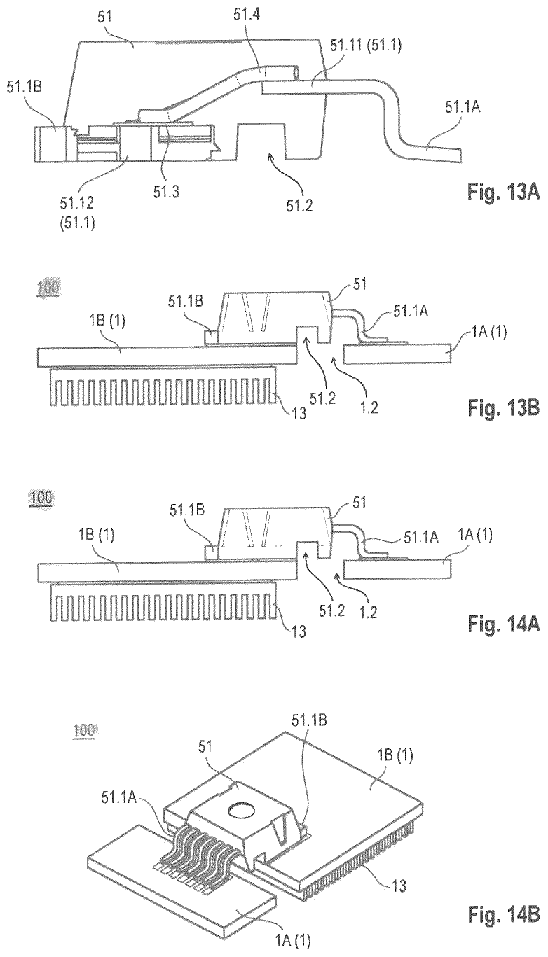

FIGS. 13A and 13B show a cross-sectional side view of an SMD leaded semiconductor package with another exemplary modified leadframe (FIG. 13A) and a semiconductor device module containing the semiconductor package with the modified leadframe with an application board having a slot (FIG. 13B).

The semiconductor package 51 as shown in FIG. 13A comprises a leadframe 51.1 which is embedded in an encapsulant. The semiconductor package 51 further comprises a groove 51.2 which corresponds to the groove 11.2 of the semiconductor package 11. The leadframe 51.1 comprises a right-side portion 51.11 which is bent upwards to extend over the groove 51.2, and a left-side portion 51.12 which comprises a die pad onto which a semiconductor transistor die 51.3 is mounted. The right-side portion 51.1 is connected with first external contacts in the form of leads 51.1A, and the left-side portion 51.12 is with second external contact elements in the form of flat external contacts 51.1B, both the first and second external contacts 51.1A and 51.1B allow surface mounting of the semiconductor package 51 onto contact areas of an application board such as a PCB. The right-side portion 51.11 of the leadframe 51.1 is connected by a thick bond wire 51.4 to the semiconductor transistor die 51.3.

The semiconductor device module 100 of FIG. 13B comprises an application board 1 like, for example, a PCB 1 such as that shown and described in FIGS. 1A and 1B, the PCB 1 comprising a slot 1.2. Furthermore the semiconductor device module 100 comprises a semiconductor package 51 as that shown in FIG. 13A mounted onto the PCB 1. Other elements of the semiconductor device module 100 correspond in their functionality to the corresponding elements of the semiconductor devices modules shown above, so that the corresponding reference numbers have been retained.

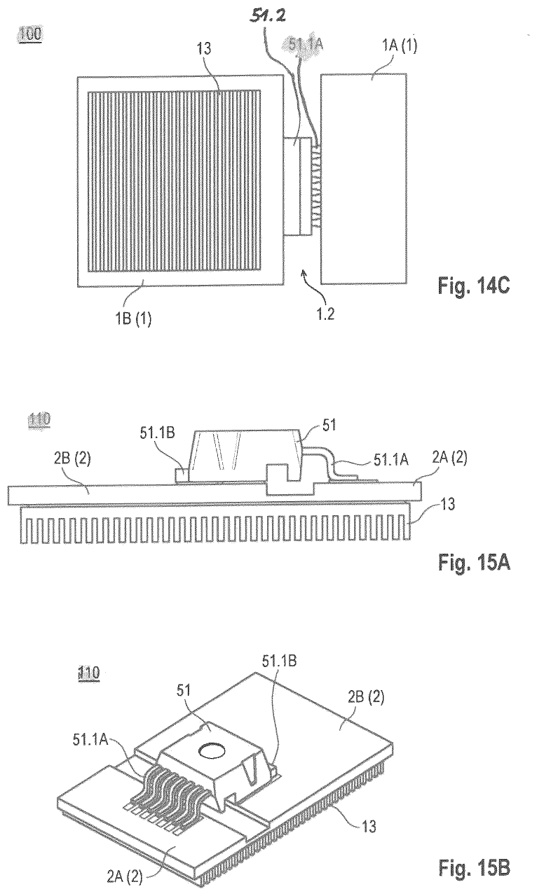

FIGS. 14A to 14C show a cross-sectional side view (FIG. 14A), a perspective view (FIG. 14B), and a bottom view (FIG. 14C) on an exemplary semiconductor device module with the same semiconductor package as the one of FIG. 13B together with an application board having a slot.

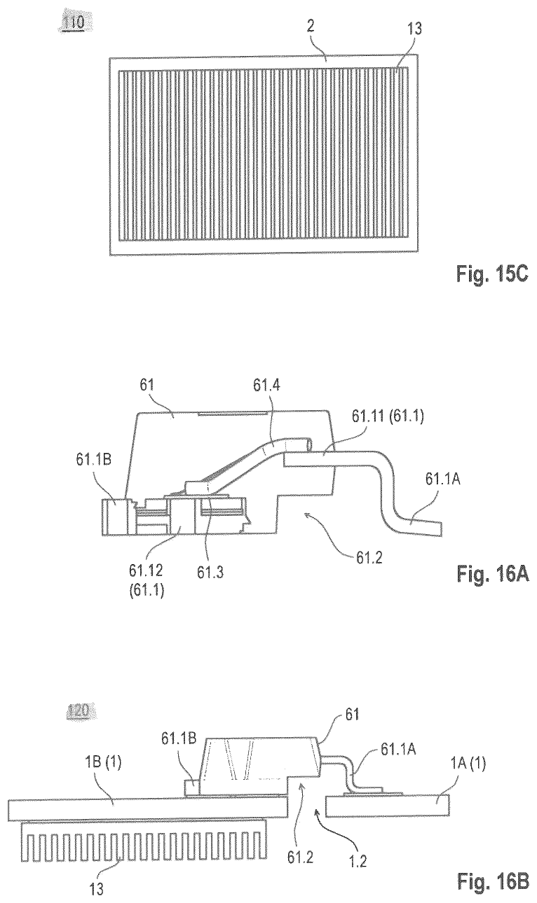

FIGS. 15A to 15C show a cross-sectional side view (FIG. 15A), a perspective view (FIG. 15B), and a bottom view (FIG. 15C) on an exemplary semiconductor device module with the same semiconductor package as the one of FIGS. 14A to 14C together with an application board having a groove.

The semiconductor device module 110 of FIGS. 15A to 15C comprises an application board 2 like, for example, a PCB 2 such as that shown and described in FIGS. 2A and 2B, the PCB 2 comprising a groove 2.2. Furthermore the semiconductor device module 110 comprises a semiconductor package 51 as shown in FIG. 13A mounted onto the PCB 2. The semiconductor package 51 is mounted onto the PCB 2 in a similar way as was shown in FIGS. 14A to 14C so that most reference numbers have been retained.

FIGS. 16A and 16B show a cross-sectional side view of another SMD leaded semiconductor package with another exemplary modified leadframe (FIG. 16A) and a semiconductor device module containing the semiconductor package with the modified leadframe with an application board having a slot (FIG. 16B).

In the previous embodiments of the semiconductor device module, the moulded recess formed in the semiconductor package was formed by a trench. In the following embodiments, the recess is provided by a recess formed at the edge of the package.

The semiconductor package 61 as shown in FIG. 16A comprises a leadframe 61.1 which is embedded in an encapsulant. The semiconductor package 61 further comprises a recess 61.2 at the edge of the semiconductor package which corresponds in its functionality to the groove 11.2 of the semiconductor package 11. The leadframe 61.1 comprises a right-side portion 61.11 which is bent upwards to extend over the groove 61.2, and a left-side portion 61.12 which comprises a die pad onto which a semiconductor transistor die 61.3 is mounted. The right-side portion 61.1 is connected with first external contacts in the form of leads 61.1A, and the left-side portion 61.12 is with second external contact elements in the form of flat external contacts 61.1B, both the first and second external contacts 61.1A and 61.1B allow surface mounting of the semiconductor package 61 onto contact areas of an application board such as a PCB. The right-side portion 61.11 of the leadframe 61.1 is connected by a thick bond wire 61.4 to the semiconductor transistor die 61.3.

The semiconductor device module 120 of FIG. 16B comprises an application board 1 like, for example, a PCB 1 such as that shown and described in FIGS. 1A and 1B, the PCB 1 comprising a slot 1.2. Furthermore the semiconductor device module 120 comprises a semiconductor package 61 as that shown in FIG. 16A mounted onto the PCB 1. Other elements of the semiconductor device module 120 correspond in their functionality to the corresponding elements of the semiconductor devices modules shown above, so that the corresponding reference numbers have been retained.

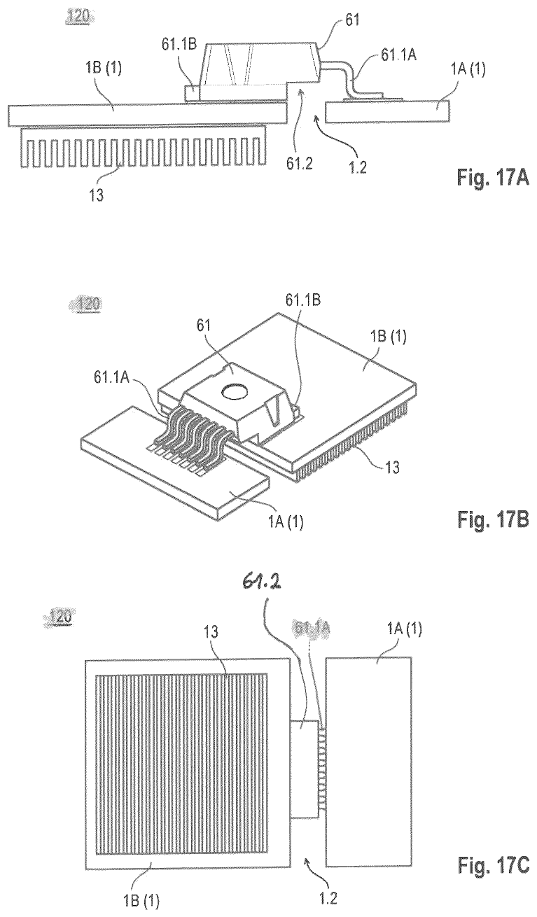

FIGS. 17A to 17C show a cross-sectional side view (FIG. 17A), a perspective view (FIG. 17B), and a bottom view (FIG. 17C) on an exemplary semiconductor device module 120 such as that shown in FIG. 16B.

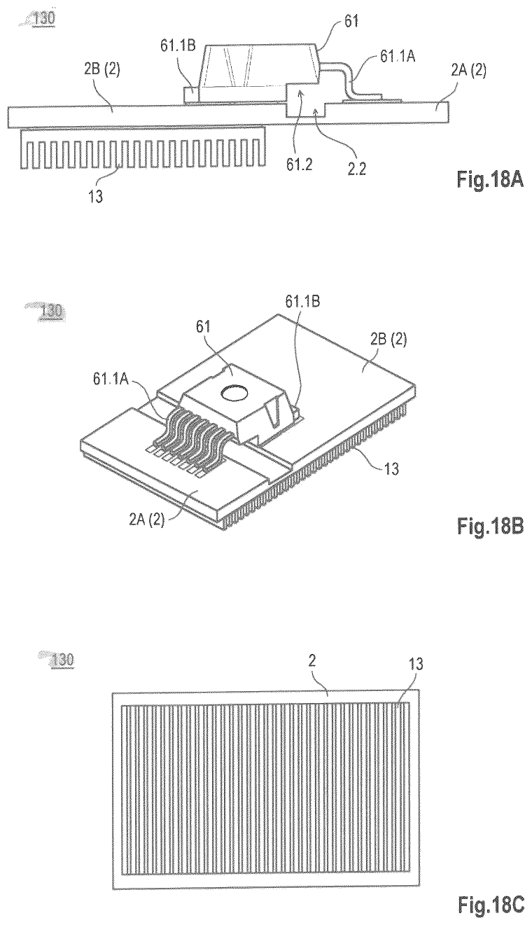

FIGS. 18A to 18C show a cross-sectional side view (FIG. 18A), a perspective view (FIG. 18B), and a bottom view (FIG. 18C) on an exemplary semiconductor device module 130 with the same semiconductor package as the one of FIG. 16B together with a PCB 2 having a groove 2.2.

In the following specific examples of the present disclosure are described.

Example 1 is an application board, comprising a first main face and a plurality of electrical contact areas disposed on the first main face, the plurality of electrical contact areas comprising one or more first electrical contact areas and one or more second electrical contact areas, and a recess, namely a slot or a groove disposed in the first main face, the recess spacing a first portion of the application board from a second portion of the application board, wherein the first electrical contact areas are disposed on the first portion of the application board and the second electrical contact areas are disposed on the second portion) of the application board.

Example 2 is the application board aaccording to Example 1, wherein the one or more first electrical contact areas are arranged on the first portion of the application board at a distance in a range between 0 mm and 3 mm from an edge of the first section facing the recess.

Example 3 is the application board aaccording to Example 1 or 2, wherein the width of the recess is in a range from 0.25 mm to 5 mm.

Example 4 is the application board aaccording to Example any one of the preceding Examples, wherein two or more first electrical contact areas are arranged side by side along a row on the first portion of the application board.

Example 5 is the application board according to any one of the preceding Examples, wherein the application board comprises one or more of a printed circuit board (PCB), direct copper bond (DCB) substrate, active metal braze (AMB) substrate, insulated metal substrate (IMS), or any other interposer.

Example 6 is a semiconductor device module, comprising an application board according to any one of the preceding Examples, and a semiconductor package mounted onto the application board.

Example 7 is the semiconductor device module according to Example 6, wherein the semiconductor package comprises a semiconductor transistor die and a plurality of external contacts comprising first external contacts and second external contacts, wherein the semiconductor transistor die comprises a load path, wherein the first external contacts are connected with the load path of the semiconductor transistor die.

Example 8 is the semiconductor device module according to Example 6 or 7, wherein the semiconductor package comprises a first main surface facing the application board, in which first main surface a recess is formed, whereby the semiconductor package is mounted on the application board in such a way that the recess of the semiconductor package comes to lie above the recess of the application board.

Example 9 is the semiconductor device module according to Example 8, wherein the recess formed in the first main surface of the semiconductor package is either a groove or a recess at an edge of the semiconductor package.

Example 10 is the semiconductor device module according to Example 8 or 9, wherein an inner lateral wall of the recess is adjacent and coplanar with an inner lateral wall of the recess of the application board.

Example 11 is the semiconductor device module according to any one of Examples 8 to 10, wherein the recess extends from a first sidewall to an opposing sidewall of the semiconductor package.

Example 12 is the semiconductor device module according to any one of Examples 6 to 11, wherein the external contacts are either bent leads or flat contacts.

Example 13 is the semiconductor device module according to any one of Examples 6 to 12, wherein the semiconductor package comprises a leadframe, wherein the leadframe comprises a die pad and a plurality of leads.

Example 14 is the semiconductor device module according to any one of Examples 6 to 13, wherein the semiconductor transistor die comprises one or more of a vertical semiconductor transistor die, a semiconductor power transistor die, an IGBT die, a MOSFET die, a JFET die, a CoolMOS die, a wide band gap semiconductor transistor die, in particular a SiC transistor die or a GaN transistor die.

Example 15 is the semiconductor device module according to any one of Examples 6 to 14, wherein the recess of the application board and the recess of the semiconductor package are filled with a dielectric encapsulant.

Example 16 is the semiconductor device module according to Example 15, wherein the dielectric encapsulant comprises one or more of a dielectric mold compound, a thermally conductive fill material, a silicone, or a silicone based material.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. An application board, comprising:
a first main face and a plurality of electrical contact areas disposed on the first main face, the plurality of electrical contact areas comprising one or more first electrical contact areas and one or more second electrical contact areas; and
a recess disposed in the first main face, the recess spacing a first portion of the application board from a second portion of the application board,
wherein the one or more first electrical contact areas are disposed on the first portion of the application board and the one or more second electrical contact areas are disposed on the second portion of the application board.

2. The application board of claim 1, wherein the one or more first electrical contact areas are arranged on the first portion of the application board at a distance in a range between 0 mm and 3 mm from an edge of the first section facing the recess.

3. The application board of claim 1, wherein a width of the recess is in a range of 0.25 mm to 5 mm.

4. The application board of claim 1, wherein two or more first electrical contact areas are arranged side by side along a row on the first portion of the application board.

5. The application board of claim 1, wherein the application board comprises one or more of a printed circuit board, direct copper bond (DCB) substrate, an active metal braze (AMB) substrate, an insulated metal substrate (IMS), or an interposer.

6. The application board of claim 1, wherein the recess is a slot.

7. The application board of claim 1, wherein the recess is a groove.

8. A semiconductor device module, comprising:
the application board of claim 1; and
a semiconductor package mounted on the application board.

9. The semiconductor device module of claim 8, wherein the semiconductor package comprises a semiconductor transistor die and a plurality of external contacts comprising a plurality of first external contacts and a plurality of second external contacts, wherein the semiconductor transistor die comprises a load path, and wherein the first external contacts are connected with the load path of the semiconductor transistor die.

10. The semiconductor device module of claim 9, wherein the external contacts are either bent leads or flat contacts.

11. The semiconductor device module of claim 9, wherein the semiconductor transistor die comprises one or more of a vertical semiconductor transistor die, a semiconductor power transistor die, an IGBT die, a MOSFET die, a JFET die, a CoolMOS die, a wide band gap semiconductor transistor die, in particular a Sic transistor die or a GaN transistor die.

12. The semiconductor device module of claim 8, wherein the semiconductor package comprises a first main surface facing the application board and in which a recess is formed, and wherein the semiconductor package is mounted on the application board such that the recess of the semiconductor package lies above the recess of the application board.

13. The semiconductor device module of claim 12, wherein the recess formed in the first main surface of the semiconductor package is either a groove or a recess at an edge of the semiconductor package.

14. The semiconductor device module of claim 12, wherein an inner lateral wall of the recess of the semiconductor package is adjacent and coplanar with an inner lateral wall of the recess of the application board.

15. The semiconductor device module of claim 12, wherein the recess formed in the first main surface of the semiconductor package extends from a first sidewall to an opposing sidewall of the semiconductor package.

16. The semiconductor device module of claim 8, wherein the semiconductor package comprises a leadframe, and wherein the leadframe comprises a die pad and a plurality of leads.

17. The semiconductor device module of claim 8, wherein the recess of the application board and the recess of the semiconductor package are filled with a dielectric encapsulant.

18. The semiconductor device module of claim 17, wherein the dielectric encapsulant comprises one or more of a dielectric mold compound, a thermally conductive fill material, a silicone, or a silicone based material.
